(19) United States
(12) Patent Application Publication
(10) Pub. No.: US 2006/0021869 A1
(43) Pub. Date: Feb. 2, 2006

(54) System for and method of ensuring accurate shadow mask-to-substrate registration in a deposition process

(75) Inventor: Thomas Peter Brody, Pittsburgh, PA (US)

Correspondence Address: THE WEBB LAW FIRM, P.C., 700 KOPPERS BUILDING, 436 SEVENTH AVENUE, PITTSBURGH, PA, 15219, US

(73) Assignee: Advantech Global, LTD, Tortola (VG)

(21) Appl. No.: 10/900,620

(22) Filed: Jul. 28, 2004

(51) Int. Cl. C23C 14/00; C23C 14/32

(52) U.S. Cl. 204/192.12; 204/298.24; 204/298.25

(57) ABSTRACT

A deposition system uses the same low coefficient of thermal expansion (CTE) material, for example, a CTE of below 10 ppm/° C. in the temperature range of 0-200° C., for forming both a shadow mask and a substrate upon which depositions occur in order to overcome the heating effects of a high-temperature deposition process, thereby ensuring a uniform expansion and contraction rate of the shadow mask and the substrate.

### BACKGROUND OF THE INVENTION

1. Field of the Invention

The present invention relates to a shadow mask for forming electronic elements on a substrate and, more particularly, to ensuring accurate shadow mask-to-substrate registration in a high-temperature deposition production system.

2. Description of Related Art

Active matrix backplanes are widely used in flat panel displays for routing signals to pixels of the display in order to produce viewable pictures. Presently, active matrix backplanes for flat panel displays are formed by a photolithography manufacturing process, which has been driven in the market by the demand for higher and higher resolution displays, which is not otherwise possible with other manufacturing processes. Photolithography is a pattern definition technique which uses electromagnetic radiation, such as ultraviolet (UV) radiation, to expose a layer of resist that is deposited on the surface of a substrate. Exemplary photolithography processing steps to produce an active matrix backplane include coat photoresist, pre-bake, soak, bake, align/expose, develop, rinse, bake, deposit layer, lift off photoresist, scrub/rinse, and dry. As can be seen, the active matrix backplane fabrication process includes numerous deposition and etching steps in order to define appropriate patterns on the backplane.

Because of the number of steps required to form an active matrix backplane with the photolithography manufacturing process, foundries of adequate capacity for volume production of backplanes are very expensive. An exemplary partial list of equipment needed for manufacturing active matrix backplanes includes glass-handling equipment, wet/dry strip equipment, glass cleaning equipment, wet clean equipment, plasma chemical vapor deposition (CVD) equipment, laser equipment, crystallization equipment, sputtering equipment, ion implant equipment, resist coater equipment, resist stripping equipment, developer equipment, particle inspection equipment, exposure systems, array filet/repair equipment, dry etch systems, anti-electrostatic discharge equipment, wet etch systems, and a clean oven. Furthermore, because of the nature of the active matrix backplane fabrication process, the foregoing equipment must be utilized in a class one or class ten clean room. In addition, because of the amount of equipment needed and the size of each piece of equipment, the clean room must have a relatively large area, which can be relatively expensive.

Alternatively, a vapor deposition shadow mask process is well known and has been used for years in microelectronics manufacturing. The vapor deposition shadow mask process is a significantly less costly and less complex manufacturing process, compared to the photolithography process. Publications disclosing vapor deposition shadow mask processes as well as related processes are disclosed in U.S. Patent Application Publication No. 2003/0228715; U.S. Patent Application Publication No. 2003/0193285; U.S. Pat. No. 6,610,179; U.S. Pat. No. 6,592,933; U.S. Pat. No. 6,410,455; and U.S. Pat. No. 5,701,055.

Presently, however, shadow mask manufacturing techniques are not favored due to the lack of sufficiently high resolution to meet today's demand for high resolution products, such as active matrix backplanes. As a result, photolithography manufacturing techniques continue to be utilized to produce such high resolution products.

In order to improve the resolution of the vapor deposition shadow mask process, the size of one or more apertures in a shadow mask and the spacing between adjacent apertures must be reduced accordingly. Therefore, the ability to maintain positional accuracy of the shadow mask in relation to the substrate during the deposition process becomes increasingly critical for ensuring proper placement of the electronic elements formed therewith. Because there are various heating effects during a high-temperature deposition process, the ability to achieve small microelectronics dimensions and, thus, high resolution, by use of the vapor deposition shadow mask process is limited by thermal errors that play a considerable role in achieving positional accuracy. For example, the materials used for forming both the shadow mask and the substrate have an associated coefficient of thermal expansion (CTE). CTE is defined as the linear dimensional change of a material per unit change in temperature. A typical substrate material for an active matrix backplane is anodized aluminum, which is aluminum atop which is grown a thin insulation layer. Aluminum has a CTE of 24 parts per million/degree Celsius (ppm/° C.). By contrast, typical materials used to form a shadow mask include nickel, stainless steel, and copper. Stainless steel has a CTE between 9.9-17.3 ppm/° C., copper has a CTE of 17 ppm/° C., and nickel has a CTE of 13.3 ppm/° C. Consequently, it is difficult to maintain proper registry between the two conjoined surfaces (i.e., the surface of the shadow mask in contact with the surface of the substrate) because of their differing CTE, which results in different rates and amounts of expansion or contraction. This CTE mismatch creates undesirable geometric errors between the shadow mask and the substrate during the deposition process. What is needed is a way to overcome the heating effects during a high-temperature deposition process and, thus, maintain positional accuracy of the shadow mask in relation to the substrate.

Therefore, what is needed, and not disclosed in the prior art, is a way to overcome the heating effects during a high-temperature deposition process whereupon the positional accuracy of a shadow mask in relation to a substrate is maintained to within desirable tolerances. Still other needs will become apparent to those of ordinary skill in the art upon reading and understanding the following detailed description.

### SUMMARY OF THE INVENTION

The invention is a method of forming a structure on a substrate. The method includes providing a substrate comprised of a dielectric layer overlaying a base layer and providing at least one deposition chamber. Each deposition chamber includes therein a material deposition source positioned in spaced relation to a shadow mask formed from the same material as the base layer. The shadow mask has at least one aperture therethrough. At least a portion of the substrate is positioned in the deposition chamber on a side of the shadow mask opposite the material deposition source with the dielectric layer facing toward the shadow mask and with the base layer facing away from the shadow mask. Material from the material deposition source is deposited onto the dielectric layer of the portion of the substrate in the deposition chamber via the at least one aperture through the shadow mask in the presence of a vacuum in the deposition chamber.

The method can further include advancing the portion of the substrate into another deposition chamber and depositing material from the material deposition source in the other deposition chamber onto at least one of (1) at least one material previously deposited on the portion of the substrate and (2) the dielectric layer of the portion of the substrate via the at least one aperture through the shadow mask of the other deposition chamber in the presence of a vacuum in the other deposition chamber. The steps set forth in this paragraph can be repeated, as necessary, until all desired materials have been deposited on the portion of the substrate.

The method can further include positioning first and second portions of the substrate in first and second deposition chambers, respectively, and depositing material(s) from the deposition sources in the first and second deposition chambers on the first and second portions of the substrate via apertures in first and second shadow masks positioned in the first and second deposition chambers in the presence of a vacuum in the first and second deposition chambers. The first portion of the substrate can then be advanced into the second deposition chamber and the second portion of the substrate can be advanced into a third deposition chamber for further deposition of materials.

The material forming the base layer and the shadow mask can be Kovar® or Invar®. The base layer and the shadow mask can be formed from a material having a coefficient of thermal expansion <10 ppm/° C. in the temperature range of 0-200° C.

The material deposited in each deposition chamber can be deposited by sputtering or vapor phase deposition.

Prior to depositing the material, the aperture of the shadow mask can be aligned with a subsection of the portion of the substrate. In response to heating during deposition, the shadow mask and the portion of the substrate expand substantially to the same extent whereupon the aperture of the shadow mask remains substantially aligned with the subsection of the portion of the substrate.

The desired materials deposited on the portion of the substrate define the structure, e.g., an electronic circuit.

The invention is also a deposition system that includes means for providing a substrate comprised of a dielectric layer overlaying a base layer and at least one deposition chamber for receiving the substrate from the means for providing. Each deposition chamber has a material deposition source positioned in spaced relation to a shadow mask formed from the same material as the base layer of the substrate. The shadow mask has at least one aperture therethrough. Means is provided for positioning at least a portion of the substrate in the deposition chamber on a side of the shadow mask opposite the material deposition source with the dielectric layer facing toward the shadow mask and with the base layer facing away from the shadow mask. Means is provided for depositing material from the material deposition source in the deposition chamber onto the dielectric layer of the portion of the substrate in the deposition chamber via the at least one aperture through the shadow mask in the presence of a vacuum in the deposition chamber.

The system can also include means for advancing the portion of the substrate into another deposition chamber and means for depositing material from the material deposition source in the other deposition chamber onto at least one of (1) the material previously deposited on the portion of the substrate and (2) the dielectric layer of the portion of the substrate via the at least one aperture through the shadow mask of the other deposition chamber in the presence of a vacuum in the other deposition chamber.

The system can also include means for positioning first and second portions of the substrate in first and second deposition chambers, respectively, and means for depositing material(s) from the material deposition sources in the first and second deposition chambers on the first and second portions of the substrate via apertures in first and second shadow masks positioned in the first and second deposition chambers in the presence of a vacuum in the first and second deposition chambers. Means can also be provided for advancing the first portion of the substrate into the second deposition chamber and for advancing the second portion of the substrate into a third deposition chamber.

Forming the substrate and, more particularly, the base layer of the substrate and each shadow mask from the same material facilitates maintenance of the positional alignment of each aperture in a shadow mask in relation to the substrate as the substrate and the shadow mask expand and contract in response to the heat produced during each deposition event. Desirably, each shadow mask and the substrate are formed of the same material having a low coefficient of thermal expansion (CTE), for example, a CTE of below 10 ppm/° C. in the temperature range of 0-200° C., thereby avoiding non-uniform expansion and contraction amounts and rates. As a result, negligible relative movement is achieved between the shadow mask and the substrate during a deposition event.

### BRIEF DESCRIPTION OF THE DRAWINGS

FIG. 1 shows a vapor deposition shadow mask production system;

FIG. 2 is a top view of an exemplary shadow mask formed from a material with a low coefficient of thermal expansion (CTE);

FIG. 3 is a top view of an exemplary multi-layer circuit formed on a substrate that is formed from a material having the same low CTE as the shadow mask of FIG. 2;

FIG. 4 is a cross-sectional view of the shadow mask of FIG. 2 aligned with the multi-layer circuit of FIG. 3 taken along lines A-A and B-B in FIGS. 2 and 3, respectively; and

FIG. 5 is a flow diagram of a method of overcoming the heating effects on the shadow mask and the substrate used in a high-temperature deposition process.

### DETAILED DESCRIPTION OF THE INVENTION

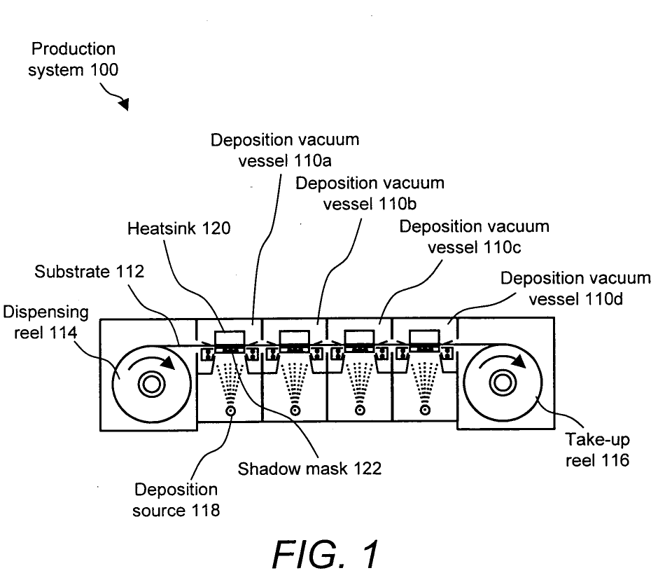

With reference to FIG. 1, a production system 100 for ensuring proper shadow mask-to-substrate alignment by use of a shadow mask and substrate material of similar CTE value in accordance with the invention, thereby minimizing any misregistration therebetween that is caused by the effects of heating, is shown. Production system 100 is representative of a system for producing an electronic device, such as an active matrix backplane that has organic light emitting diodes (OLEDs) deposited thereon.

An exemplary, non-limiting, production system 100 is described in U.S. Patent Application Publication No. 2003/0228715, entitled, “Active Matrix Backplane For Controlling Controlled Elements And Method Of Manufacture Thereof” which is incorporated herein by reference. The '715 publication describes an electronic device formed from electronic elements deposited on a substrate. The electronic elements are deposited on the substrate by the advancement of the substrate through a plurality of deposition vacuum vessels that have at least one material deposition source and a shadow mask positioned therein. The material from at least one material deposition source positioned in each deposition vacuum vessel is deposited on the substrate through the shadow mask that is positioned in the deposition vacuum vessel in order to form on the substrate a circuit formed of an array of electronic elements. The circuit is formed solely by the successive deposition of materials on the substrate.

Production system 100 includes a plurality of series connected deposition vacuum vessels 110 (e.g., deposition vacuum vessels 110a, 110b, 110c, and 110d). Production system 100 is not to be construed as limited to four deposition vacuum vessels 110 since the number of deposition vacuum vessels 110 comprising production system 100 is dependent upon the number of deposition events required for any given product formed therewith.

In operation of production system 100, a substrate 112 translates through serially arranged deposition vacuum vessels 110 by use of a reel-to-reel mechanism that includes a dispensing reel 114 and a take-up reel 116. Each deposition vacuum vessel 110 includes therein at least one deposition source 118, at least one heatsink 120 and at least one shadow mask 122.

Each deposition source 118 is charged with a desired material to be deposited onto flexible substrate 112 through a corresponding shadow mask 122. Each heatsink 120 provides a flat reference surface that is in contact with the non-deposition side of substrate 112 and which serves as a heat removal means for substrate 112 as it translates through the corresponding deposition vacuum vessel 110. Those skilled in the art will appreciate that production system 100 may include additional stages (not shown), such as an anneal stage, a test stage, one or more cleaning stages, a cut and mount stage, and the like. In addition, the number, purpose and arrangement of deposition vacuum vessels 110 and any other additional stages (not shown) can be modified as needed for depositing one or more materials required for a particular application.

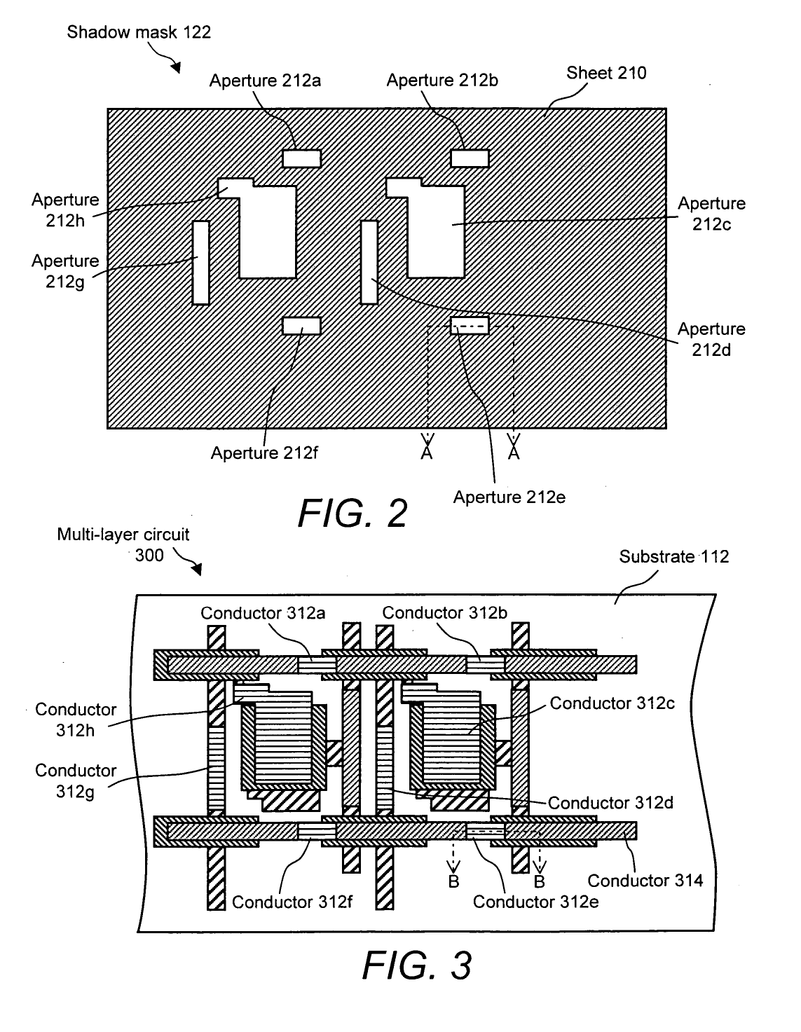

With reference to FIG. 2 and with continuing reference to FIG. 1, each shadow mask 122 includes a pattern of apertures (not shown), e.g., slots, holes and the like. The pattern of apertures in each shadow mask 122 corresponds to a desired pattern of material to be deposited on substrate 112 from the corresponding deposition source 118 as substrate 112 is advanced or translates through the corresponding deposition vacuum vessel 110.

Deposition vacuum vessels 110 can be utilized for depositing materials on substrate 112 to form an electric circuit on substrate 112. This electric circuit can include one or more electronic elements such as a thin film transistor (TFT), a diode, a memory element, or a capacitor that is also formed by the deposition of materials on substrate 112. A multi-layer electric circuit, such as multi-layer circuit 300 shown in FIG. 3, can be formed solely by the successive deposition of materials on substrate 112 via the successive operation of each deposition vacuum vessel 110.

Each deposition vacuum vessel 110 is connected to a source of vacuum (not shown) for establishing a suitable vacuum therein. More specifically, the source of vacuum establishes a suitable vacuum in each deposition vacuum vessel 110 in order to enable a charge of the desired material in each deposition source 118 to be deposited on substrate 112 in a manner known in the art, e.g., sputtering or vapor phase deposition, through one or more apertures of the corresponding shadow mask 122.

In the following description of production system 100, substrate 112 will be described as being a continuous, flexible sheet which is initially disposed on a dispensing reel 114 that dispenses substrate 112 into the first deposition vacuum vessel 110. However, this is not to be construed as limiting the invention since production system 100 can be configured to process one or more individual substrates 112.

Dispensing reel 114 is positioned in a preload vacuum vessel, which is connected to a source of vacuum (not shown) for establishing a suitable vacuum therein. Each deposition vacuum vessel 110 includes supports or guides that avoid substrate 112 from sagging as it advances or translates therethrough.

In operation of production system 100, the material received in each deposition source 118 is deposited on substrate 112 through a shadow mask 122 in the presence of a suitable vacuum as substrate 112 is advanced through the corresponding deposition vacuum vessel 110, whereupon plural progressive patterns are formed on substrate 112. More specifically, substrate 112 has plural portions that are positioned for a predetermined interval in each deposition vacuum vessel 110. During this predetermined interval, material is deposited from one or more deposition sources 118 onto the portion of substrate 112 that is positioned in the corresponding deposition vacuum vessel 110. After this predetermined interval, substrate 112 is step advanced whereupon the plural portions of substrate 112 are advanced to the next deposition vacuum vessel 110 in series for additional processing, as applicable. This step advancement continues until each portion of substrate 112 has passed through all deposition vacuum vessels 110. Thereafter, each portion of substrate 112 exiting the final deposition vacuum vessel 110 in the series of deposited vacuum vessels 110 is received on take-up reel 116 which is positioned in a storage vacuum vessel. Alternatively, each portion of substrate 112 exiting deposition vacuum vessel is separated from the remainder of substrate 112 by a cutter (not shown).

An exemplary shadow mask 122 is formed of a material that has a low CTE, for example, a CTE of below 10 ppm/° C. in the temperature range of 0-200° C. Each shadow mask includes a sheet 210 that is formed of a low CTE material, such as Kovar® or Invar®, which can be obtained in sheet form from, for example, ESPICorp Inc. (Ashland, Oreg.). Kovar® is a registered trademark, Registration Nos. 337,962, currently owned by CRS Holdings, Inc. of Wilmington, Del. Invar® is a registered Trademark, Registration No. 63,970, currently owned by Imphy S.A. Corporation of France. Formed within sheet 210 is a pattern of apertures 212, each of which is an opening of a predetermined size, shape and location according to an associated portion of a multi-layer circuit 300.

With reference to FIG. 3 and with continuing reference to FIGS. 1 and 2, exemplary multi-layer circuit 300 is formed upon substrate 112 which, like sheet 210, is formed of a low CTE material, such as Kovar® or Invar®, upon which is deposited multiple layers of conductors, such as a plurality of conductors 312 and a conductor 314 for forming multi-layer circuit 300. Multi-layer circuit 300 is formed via successive deposition events by use of successive shadow masks 122 in production system 100.

Apertures 212a, 212b, 212c, 212d, 212e, 212f, 212g, and 212h of shadow mask 122, which is formed of a low CTE material, are associated with the formation of conductors 312a, 312b, 312c, 312d, 312e, 312f, 312g, and 312h, respectively, upon substrate 112 of multi-layer circuit 300, which is, likewise, formed of the same low CTE material.

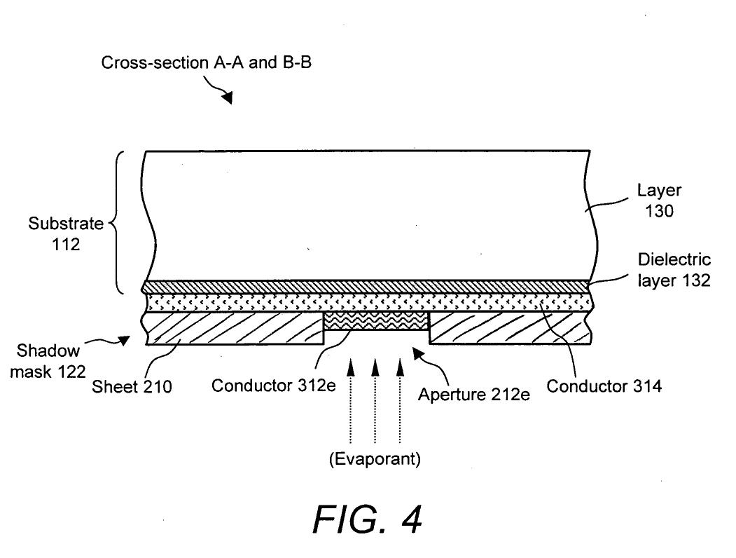

With reference to FIG. 4 and with continuing reference to FIGS. 1-3, a cross-sectional view of shadow mask 122 aligned with multi-layer circuit 300 formed on substrate 112, taken along lines A-A and B-B of FIGS. 2 and 3, respectively, shows shadow mask 122 in physical contact with substrate 112 upon which the deposition event takes place. In this example, the material forming conductor 312e is deposited by the material evaporated from one deposition source 118 as the evaporated material passes through aperture 212e of shadow mask 122.

Substrate 112 is formed of a base layer 130 of a low CTE material, such as Kovar® or Invar®, upon which is formed a dielectric layer 132, e.g., a thin layer of anodized aluminum oxide, which serves as an insulation layer upon which conductors are deposited. The disclosure of dielectric layer 132 being a thin layer of anodized aluminum oxide, however, is not to be construed as limiting the invention since dielectric layer 132 may be formed of any suitable and/or desirable insulating material. Base layer 130 of substrate 112 is, for example, 100-150 microns thick. Dielectric layer 132 of substrate 112 is, for example, a few hundred nanometers thick. Sheet 210 of shadow mask 122 is, for example, 2-25 microns thick. The foregoing thicknesses of substrate 112, dielectric layer 132 and shadow mask 122, however, are not to be construed as limiting the invention.

Kovar® is an iron-nickel-cobalt alloy. The chemistry is closely controlled, so as to result in low, uniform, thermal expansion characteristic for the alloy. It finds use in applications for which low expansion with temperature change is a desired characteristic, such as integrated circuits packaging.

Kovar®'s general properties include:
Symbol: Ni, Fe, Co alloy;
Weight Percent: 29% Ni, 17% Co, 53% Fe, and 1% trace;
Density: 8.36 g/cm³;
Melting Point: 2642° F. (1450° C.);
Thermal Conductivity: 16.8 W/mk; and
nominal CTE: 30-200° C.=5.5 ppm/° C.;
   30-300° C.=5.1 ppm/° C.;
   30-400° C.=4.9 ppm/° C.;
   30-450° C.=5.3 ppm/° C.;
   30-500° C.=6.2 ppm/° C.;
   30-600° C.=7.9 ppm/° C.;
   30-700° C.=9.3 ppm/° C.;
   30-800° C.=10.4 ppm/° C.; and
   30-900° C.=11.5 ppm/° C.

Invar® is a 36% iron-nickel austenitic alloy and has the lowest thermal expansion among all metal alloys in the range from room temperature up to approximately 230° C. It is strong, tough, ductile, and possesses a useful degree of corrosion resistance. It is magnetic at temperatures below its Curie point and non-magnetic at temperatures above. Invar® is, therefore, always magnetic in the temperature range in which it exhibits the low-expansion characteristics. Invar® is a very low coefficient of thermal expansion nickel-iron alloy and can be used for shadow masks, frames and cathode ray tube gun parts. The alloy is easily weldable and its machinability is similar to austenitic stainless steel. It does not suffer from stress corrosion cracking. The mean CTE of Invar® from 20-100° C. is less than 1.3 ppm/° C.; its Curie point is 230° C.; and its density is 8.1 kg/m³. There is an alloy called Super Invar that has a smaller coefficient of thermal expansion, less than 0.63 ppm/° C., and, in some cases, negative whereupon the alloy reduces its length when temperature increase.

Invar®'s general properties include:
Specific Gravity: 8.08;
Melting Point: 2600° F.;
Density: 0.292 lb/in³;
Specific Heat: 0.123 BTU/lb/° F.;
Thermal Conductivity: 72.6 BTU/ft²/in/° F./hr;
Specific Gravity: 8.08;
Melting Point: 2600° F.;
Density: 0.292 lb/in³; and
nominal CTE: −200-0° F.=1.1 ppm/° F.;
   0-200° F.=0.7 ppm/° F.;
   200-400° F.=1.5 ppm/° F.;
   400-600° F.=6.4 ppm/° F.;
   600-800° F.=8.6 ppm/° F.; and
   800-1000° F.=9.5 ppm/° F.

With continuing reference to FIGS. 1-4, shadow mask 122 is aligned and held in physical contact with substrate 112 within a given deposition vacuum vessel 110 of production system 100. During deposition of a material in a deposition vacuum vessel 110, the temperature of the corresponding shadow mask 122 and portion of substrate 112 upon which the material is being deposited may typically be in the range of 20 to 100° C. The low CTE material that forms sheet 210 of shadow mask 122 absorbs the heat produced during deposition and transfers this heat to substrate 112. Because sheet 210 of shadow mask 122 and layer 130 of substrate 112 are formed of the same CTE material, such as Kovar® or Invar®, geometric changes in layer 130 and in substrate 112 resulting from expansion at an elevated temperature are similar. As a result, and because of the minimal thermal expansion and the compatibility of the CTE of the materials forming both shadow mask 122 and substrate 112, distortion, induced stress and warping of shadow mask 122 and substrate 112 are avoided. Even with marginal expansion or contraction, there is minimal or negligible relative movement between shadow mask 122 and substrate 112 at an elevated temperature. Thus, shadow mask 122 and substrate 112 remain aligned, i.e., the apertures 212 of shadow mask 122 continue to align properly with a specific subsection of the portion of substrate 112 upon which the material is being deposited, thereby enabling accurate formation of multi-layer circuit 300 on substrate 112.

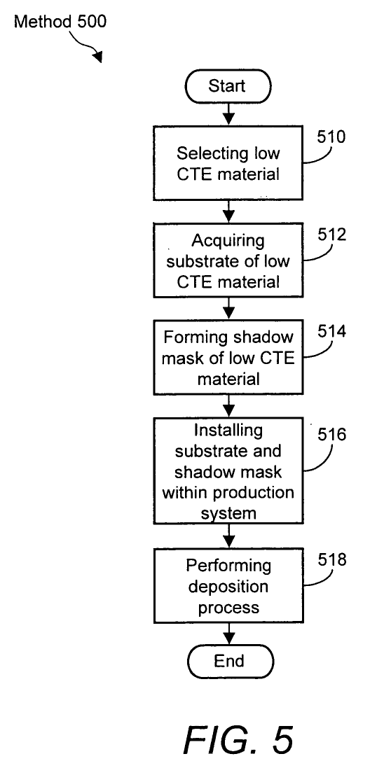

With reference to FIG. 5 and with continuing reference to FIGS. 1-4, a flow diagram of a method 500 of overcoming the heating effects upon the shadow mask and the substrate that are used in a high-temperature deposition process, thereby facilitating proper positional accuracy of the shadow mask in relation to the substrate, includes step 510 wherein a material that has suitable characteristics for use as both a substrate material and a shadow mask material in a high-temperature deposition process is selected. In particular, a material having a low CTE, for example, a CTE of below 10 ppm/° C. in the temperature range of 0-200° C., is selected. Example materials include Kovar® and Invar®.

In step 512, a substrate, such as substrate 112, which is formed from the low CTE material, such as Kovar® and Invar®, selected in step 510, is acquired from a supplier in the form of a continuous sheet on a reel or as individual segments of material.

In step 514, a shadow mask, such as shadow mask 122, is formed from the low CTE material, such as Kovar® and Invar®, selected in step 510. The shadow mask includes a plurality of apertures, such as apertures 212, arranged according to a predetermined pattern.

In step 516, one or more substrates, such as one or more substrates 112, and one or more shadow masks, such as one or more shadow masks 122, are positioned within a deposition system, such as production system 100, for the production of, for example, an electronic circuit.

In step 518, a deposition process, such as the deposition process described above with reference to production system 100, is performed. Within each deposition vacuum vessel 110, a shadow mask 122 is aligned and held in physical contact with substrate 112. During deposition, the temperature of shadow mask 122 and substrate 112 will typically increase into the range of 20 to 100° C. The low CTE material that forms sheet 210 of shadow mask 122 absorbs the heat produced during deposition and the resulting thermal transfer of this heat through sheet 210 causes substrate 112 to, likewise, absorb heat. Because sheet 210 of shadow mask 122 and layer 130 of substrate 112 are formed of the same low CTE material, such as Kovar® or Invar®, geometric changes in layer 130 and in substrate 112 resulting from expansion at an elevated temperature are similar. As a result and because of the minimal thermal expansion and the compatibility of the CTE of the materials forming both shadow mask 122 and substrate 112, distortion, induced stress, and warping of the two bodies are avoided, thereby minimizing any misregistration therebetween caused by the effects of heating, i.e., aperture(s) 212 of shadow mask 122 continue to align properly with a specific subsection of substrate 112 during deposition thereby enabling the accurate formation of multi-layer circuit 300 on substrate 112. Thereafter, method 500 ends.

The present invention has been described with reference to the preferred embodiment. Obvious modifications and alterations will occur to others upon reading and understanding the preceding detailed description. It is intended that the invention be construed as including all such modifications and alterations insofar as they come within the scope of the appended claims or the equivalents thereof.

The invention claimed is:

1. A method of forming a structure on a substrate comprising:
(a) providing a substrate comprised of a dielectric layer overlaying a base layer;
(b) providing at least one deposition chamber, with each deposition chamber having a material deposition source positioned in spaced relation to a shadow mask formed from the same material as the base layer, the shadow mask having at least one aperture therethrough;
(c) positioning at least a portion of the substrate in the deposition chamber on a side of the shadow mask opposite the material deposition source with the dielectric layer facing toward the shadow mask and with the base layer facing away from the shadow mask; and
(d) depositing material from the material deposition source in the deposition chamber onto the dielectric layer of the portion of the substrate in the deposition chamber via the at least one aperture through the shadow mask in the presence of a vacuum in the deposition chamber.

2. The method of claim 1, further including:
(e) advancing the portion of the substrate into another deposition chamber;
(f) depositing material from the material deposition source in the other deposition chamber onto at least one of (1) at least one material previously deposited on the portion of the substrate and (2) the dielectric layer of the portion of the substrate via the at least one aperture through the shadow mask of the other deposition chamber in the presence of a vacuum in the other deposition chamber; and
(g) repeating steps (e)-(f), as necessary, until all desired materials have been deposited on the portion of the substrate.

3. The method of claim 2, further including:
positioning first and second portions of the substrate in first and second deposition chambers, respectively;
depositing material(s) from the deposition sources in the first and second deposition chambers on the first and second portions of the substrate via apertures in first and second shadow masks positioned in the first and second deposition chambers in the presence of a vacuum in the first and second deposition chambers;
advancing the first portion of the substrate into the second deposition chamber; and
advancing the second portion of the substrate into a third deposition chamber.

4. The method of claim 1, wherein the material forming the base layer and the shadow mask is one of Kovar® and Invar®.

5. The method of claim 1, wherein the base layer and the shadow mask are formed from a material having a coefficient of thermal expansion <10 ppm/° C. in the temperature range of 0-200° C.

6. The method of claim 1, wherein the material in step (d) is deposited by one of sputtering and vapor phase deposition.

7. The method of claim 1, wherein:
prior to depositing the material, the aperture of the shadow mask is in alignment with a subsection of the portion of the substrate; and
in response to heating during deposition, the shadow mask and the portion of the substrate expand substantially to the same extent whereupon the aperture of the shadow mask remains substantially aligned with the subsection of the portion of the substrate.

8. The method of claim 2, wherein the desired materials deposited on the portion of the substrate define the structure.

9. The method of claim 2, wherein the structure is an electronic circuit.

10. A deposition system comprising:
means for providing a substrate comprised of a dielectric layer overlaying a base layer;
at least one deposition chamber for receiving the substrate from the means for providing, with each deposition chamber having a material deposition source positioned in spaced relation to a shadow mask formed from the same material as the base layer, the shadow mask having at least one aperture therethrough;
means for positioning at least a portion of the substrate in the deposition chamber on a side of the shadow mask opposite the material deposition source with the dielectric layer facing toward the shadow mask and with the base layer facing away from the shadow mask; and
means for depositing material from the material deposition source in the deposition chamber onto the dielectric layer of the portion of the substrate in the deposition chamber via the at least one aperture through the shadow mask in the presence of a vacuum in the deposition chamber.

11. The system of claim 10, further including:
means for advancing the portion of the substrate into another deposition chamber; and
means for depositing material from the material deposition source in the other deposition chamber onto at least one of (1) the material previously deposited on the portion of the substrate and (2) the dielectric layer of the portion of the substrate via the at least one aperture through the shadow mask of the other deposition chamber in the presence of a vacuum in the other deposition chamber.

12. The method of claim 11, further including:
means for positioning first and second portions of the substrate in first and second deposition chambers, respectively;
means for depositing material(s) from the material deposition sources in the first and second deposition chambers on the first and second portions of the substrate via apertures in first and second shadow masks positioned in the first and second deposition chambers in the presence of a vacuum in the first and second deposition chambers;
means for advancing the first portion of the substrate into the second deposition chamber; and
means for advancing the second portion of the substrate into a third deposition chamber.
